(19) United States
(12) Patent Application Publication
(10) Pub. No.: US 2012/0073623 A1
(43) Pub. Date: Mar. 29, 2012

(54) Flexible, Modular, Solar Cell Assembly

(75) Inventors: Hugh W. Jones, Canastota, NY (US); Evan H. Jones, Canastota, NY (US)

(73) Assignee: ENERGY MASTERS, LLC, Canastota, NY (US)

(21) Appl. No.: 13/246,264

(22) Filed: Sep. 27, 2011

Related U.S. Application Data
(60) Provisional application No. 61/386,698, filed on Sep. 27, 2010.

(51) Int. Cl. H01L 31/045; H01L 31/18

(52) U.S. Cl. 136/245; 29/890.033

(57) ABSTRACT

A solar module having a six layer stack structure, including the following layers: (i) first plastic layer (e.g., ETFE layer); (ii) second plastic layer (e.g., uppermost EVA layer); (iii) solar cell layer; (iv) third plastic layer (e.g., intermediate EVA layer); (v) fiber panel; and (vi) fourth plastic layer (e.g., lowermost EVA layer). This six layer module is detachably attached to a seventh layer of rip stop backing material layer (or other pliable fabric). Generally, many solar modules will be: (i) mechanically detachably attached to the larger flexible substrate member; and (ii) electrically detachably connected to each other. Sufficient space should be left between the modules on the substrate so that the substrate can be folded in the spaces between the modules.

### RELATED APPLICATION

The present application claims priority to U.S. provisional patent application No. 61/386,698, filed on 27 Sep. 2010; all of the foregoing patent-related document(s) are hereby incorporated by reference herein in their respective entirety(ies).

### BACKGROUND OF THE INVENTION

1. Field of the Invention

The present invention relates generally to solar cell assemblies, more particularly to modular, flexible, transportable solar cell assemblies and even more particularly to solar cell assemblies having a multiplicity of monocrystalline or polycrystalline solar cells arranged in a generally flat and planar arrangement.

2. Description of the Related Art

Photovoltaic (for example, solar) cell assemblies (or “solar panels”) are well known in the art of alternate energy devices. There are at least three known types of solar cells as follows: (i) monocrystalline; (ii) polycrystalline; and (iii) thin film. The present invention relates primarily to assemblies with monocrystalline/polycrystalline cells. Unlike thin film solar cells, it is difficult or impossible to bend monocrystalline or polycrystalline solar cells. It is known that mono-crystalline cells are more efficient than thin film cells, although thin film cells are often used because they are more convenient to work with.

Solar panels operate essentially by being placed in the path of sunlight Each solar panel is made up of many photovoltaic (or PV or solar) cells. The PV cells absorb the sunlight because of the special materials out of which the PV cells are made. Embedded within the solar cell are two different semiconducting layers: the p-type and the n-type. The p-type has an abundance of electrons and the n-type has relatively few electrons. When exposed to incoming sunlight, the radiation of the sunlight will knock off a few negatively-charged electrons from atoms in the electron-heavy p-type material, and these energized electrons flow through the electron-barren n-type material. This constant one-way flow of electrons creates a direct current. The energized electrons flow through a circuit, are made to do electrical work charging batteries or powering light bulbs, and are sent back into the p-type layer to be energized again. In addition, the Applicant's website accessible at the URL at www.energymasters.com, the content of which is hereby incorporated by reference, provides information on its STAR assembly which is another example of a flexible solar cell assembly.

Solar cell assemblies that are flexible/foldable and transportable (for example, lightweight) are useful in applications requiring rapid deployment of alternate energy devices, such as: (i) providing power to run water filtration equipment in areas hit by natural disasters and without a direct source of electrical energy (for example, in Haiti following the 2009 earthquake); (ii) providing power for military equipment in the field; and (iii) many other applications.

Some prior art solar cell assemblies are manufactured using a laminating process to form a one-piece units. In these units, the solar cells are compressed and become an integral part of the common backing material. For example, the common backing material may take the form of an aluminum sheet. These one-piece units are useful when flexibility and portability are part of the design criteria. Once a collection of solar cells have been laminated, they are stitched to a flexible material, such as nylon. Then, wires are embedded within the nylon and electrically interconnect the laminated sheet one-piece cells so that the direct current electrical energy, generated by the cells' reaction to solar radiation, can be transported to a battery for storage. The battery then, on an as-needed basis, releases its stored energy, received from the cells, and through the solar panel wiring. Generally, the battery will release DC electric energy. These prior art solar panels are effective when used in direct sunlight, and so long as the wiring remains intact. However, with this common arrangement, electrical energy (in the form of direct current) tends to leak from the battery back into the cells. Furthermore, if the solar panel used in partial shade, certain of the cells will be required to carry enough current to support the load, which can cause overheating and damage to the unit as a whole. Furthermore, the failure of a single laminated cell will render the entire solar panel useless.

US patent application (“USPA”) 2011/0108084 (“084 Tisler”) discloses a photovoltaic module that includes solar cells and diodes. At FIGS. 11 and 12, Tisler discloses an embodiment of a solar cell assembly where a flexible diode assembly is utilized as a blocking diode assembly to perform a current blocking function. Tisler discloses that its flexible diode assembly may also be utilized as a blocking diode assembly in its PV module. (084 Tisler at paragraph 0032.)

USPA 2010/0240153 (“153 Tabe”) discloses a manufacturing process for making photovoltaic modules. There is a point in the manufacturing process where solar cells are inspected for defects, and, if a defect is found in a given solar cell, then that solar cell is removed and replaced. (See 153 Tabe at paragraphs 0014, 0061 and 0062.) After these inspection and selective replacement stops are completed, the manufacturing process continues until a finished solar panel assembly is completed. (See 153 Tabe at paragraphs 15 and 0063-0066.) 153 Tabe does not teach or suggest that a solar cell may be replaced from the solar panel after the finished solar panel has been completely manufactured.

USPA 2010/0224239 (“239 Sharps) discloses a solar cell assembly with a bypass diodes for electrically bypassing defective solar cell(s).

USPA 2010/0101627 (“627 Patel”) discloses a flexible solar panel module. (See 627 Patel at paragraph 0005.)

USPA 2009/0229596 (“596 Shin”) discloses a method of electrically eliminating defective solar cell units that are located in an integrated solar cell module. More specifically, 596 Shin uses repair pads and connective bridges as its bypass circuitry. The connective bridges may be selectively created or modified depending upon location(s) of bad cell(s). (See 596 Shin at ABSTRACT.)

USPA 2002/0059952 (“952 Shimada”) discloses a solar cell battery module with removable and replaceable solar cells. (See 952 Shimada at ABSTRACT.)

USPA 2002/0066828 (“828 Nakamura”) discloses a solar panel with solar cells that are removable and replaceable from the larger solar panel assembly. (See 828 Nakjamura at paragraphs 0020-0025.)

The following published documents may also include helpful background information: (i) US patent application 2003/0196691 (“691 Gerson”); (ii) USPA 2003/0150484 (“484 Winkeler”); and/or (iii) PCT publication WO/2005/078808 (“Solar Roofing System”).

Description of the Related Art Section Disclaimer

To the extent that specific publications are discussed above in this Description of the Related Art Section, these discussions should not be taken as an admission that the discussed publications (for example, published patents) are prior art for patent law purposes. For example, some or all of the discussed publications may not be sufficiently early in time, may not reflect subject matter developed early enough in time and/or may not be sufficiently enabling so as to amount to prior art for patent law purposes. To the extent that specific publications are discussed above in this Description of the Related Art Section, they are all hereby incorporated by reference into this document in their respective entirety(ies).

### BRIEF SUMMARY OF THE INVENTION

One aspect of the present invention of the present invention is a solar panel including a plurality of solar modules (see DEFINITIONS section) removably connected to a flexible sheet substrate. In some preferred embodiments, the detachably attachable mechanical connection between each module and the flexible substrate sheet is made (in whole or in part) by a heat releasable chemical bonding agent, such as EVA. The detachable attachment may be may (in whole or in part) by other types of detachably attachable securement hardware, such as removable rivets or corner pocket structures. Each solar cell module is electrically interconnected to an electrically-adjacent module by wiring connectors that extend off of each module. Each module preferably includes a laminated package of a predetermined number of solar cells sandwiched between two plates of substrate, preferably ethylene vinyl acetate (EVA). The wires inside of a laminated solar module package will herein be called a “wire set.” Preferably, the wire set electrically interconnects the cells the cells of the panel in series. The wire set will generally include at least two terminals that extend outside of the laminated package in order to form electrical connections with other modules or other external components. In some preferred embodiments, the each of the terminals of the wire set terminate in either a male or female connector that can form detachably attachable electrical connections.

In some preferred embodiments, a module (or encapsulated assembly) is made, and electrically and mechanically connected to the larger panel assembly, as follows: (i) an ethylene tetrafluoroethylene (ETFE) encapsulating sheet is mounted to an outer-facing side of one of the EVA sheets; (ii) a substrate panel (typically made of garolite or carbon/NOMEX fiber panel) is mounted to the inwardly facing surface of another EVA sheet; (iii) yet another EVA panel is used to sandwich the garolite or carbon/Nomex fiber panel; and (iv) the sub-assembly assembled in the foregoing steps is heat-pressed (or otherwise detachably attached) to a larger flexible substrate (for example, nylon rip stop backing material). In some (not currently preferred) embodiments, rivets are used to detachably mechanically interconnect the solar module to the larger flexible substrate, but these rivets must be sufficiently removable so that the solar module can later be removed from the larger flexible substrate without destroying either the solar module and/or the larger flexible substrate.

The preferred solar cells for use in the present invention are polycrystalline or monocrystalline solar cells (as opposed to thin film solar cells). The present invention allows a solar cell assembly that simultaneously: (i) has a multiplicity of non-foldable, non-pliable, non-flexible solar cells (for example, monocrystalline cells); and (ii) can be folded into a folded configuration. The solar modules of the present invention preferably have a layered assembly, with plastic encapsulation layer(s) above and below the layer with the solar cell(s) (preferably more than one, preferably six) and the associated wire set. While the wire set interconnecting the solar cell(s) of the module is generally substantially encapsulated in the main heat-pressed and laminated body of the solar module, the terminating ends of the wire set extend out of the of the encapsulated assembly so that the solar module can be electrically connected to other components of the solar cell assembly. Preferably, the wire set electrically connects multiple cells inside of a single encapsulated module in series.

Preferably the plurality of solar modules on a single larger, flexible substrate are connected: (i) to each other in a daisy chain fashion to form a electrical series connection between all the modules of the solar cell assembly; and (ii) such that the first and last modules are electrically connected to a wire harness that is preferably built into the larger, flexible substrate. This wire harness may have one or more diodes to prevent back flow of current and/or current flow through non-operating cells. As will be appreciated by those of skill in the art, if the solar cell assembly is being used to charge a battery (as it often is used), then the aggregate voltage of the solar cells of the solar cell assembly should generally somewhat exceed the nominal voltage of the battery for effective charging.

Multiple solar modules can be made as described in the preceding paragraph and detachably mechanically connected to a common nylon rip stop backing member to form a solar cell assembly (which can be mounted on a frame and placed in the sunlight in order to make electricity). The male/female connectors terminating the respective wiring harnesses are then used to electrically interconnect the multiple modules to each other. This process continues for as many modules as desired. The end modules having their terminal wiring ends may then be attached to the terminals of a battery. A blocking diode is bridged between the hot and neutral conducting wires adjacent the battery terminals to prevent leakage of current back into the solar cell assembly (taken as a whole). In addition, bypass diodes can be mounted to the wiring harnesses between a predetermined number of cells (for example, every 12 cells) to prevent current leakage within the solar cell assembly. Diodes of this sort are described in U.S. Pat. No. 6,690,041 which is hereby incorporated by reference.

The wiring harness employed in the present panel preferably comprises flat wire to minimize the thickness of the unit when it is in a folded condition. In addition, the wiring is preferably insulated and positioned exteriorly of the nylon backing sheet to which each of the solar cell modules are individually connected. Using insulated wire provides a more durable conductive pathway while positioning it on the exterior of the nylon backing sheet provides for a less complicated manufacturing process (because the wiring does not need to be stitched into the fabric backing).

Various embodiments of the present invention may exhibit one or more of the following objects, features and/or advantages:

(i) a flexible, portable solar panel having individually replaceable, laminated solar cell modules where the solar modules and/or their constituent solar modules are not pliable and not foldable, but where the solar cell assembly as a whole can be folded into a folded configuration for easier transport;

(ii) an improved interconnect wiring construction for the solar panel;

(iii) a solar cell panel that prevents current from leaking from its battery (or other load) back into the interconnect wiring;

(iv) other objects and advantages of the present invention will be understood by those of skill in the art based on the descriptions in this document;

(v) a solar cell assembly having a plurality of modules where individual modules can be repaired or replaced after the solar cell assembly has initially been constructed and put into use; and/or

(vi) a solar cell assembly with a relatively large watts/unit weight parameter.

According to an aspect of the present invention, a solar panel assembly includes: a first securement hardware set; a first solar module; and a flexible substrate sub-assembly. The flexible substrate sub-assembly comprises a first flexible member. The first securement hardware set is structured, located, sized, shaped and/or connected so that the first securement hardware set mechanically connects the first solar module to the flexible substrate member in a detachably attachable manner. The first solar module comprises a first set of solar cell(s) and a first wire set. The first wire set comprises an input terminal and an output terminal. The first wire set is structured, located, sized, shaped and/or connected to provide a current path from each solar cell of the first set of solar cells to the input and output terminals of the first wire set.

According to a further aspect of the present invention, a solar panel is used to convert solar radiation into electricity. The method includes the following steps (not necessarily performed in the following order except to the extent indicated). Assembling step: assembling a solar cell assembly comprising a plurality of solar modules and a flexible substrate member sub-assembly. Deploying step: deploy plurality of solar cell assemblies. Inspecting step: inspect solar assemblies to determine consumed or non-functioning solar module(s); replacing step: (subsequent to the deploying step) replacing consumed or non-functioning solar module(s). Continuing to operate step: (subsequent to the replacing step) continuing to operate the solar cell assembly to generate electricity. At the assembling step: (i) the plurality of solar modules are mechanically detachably attached to the flexible substrate member sub-assembly, and (ii) the solar modules are electrically detachably connected to each other. At the replacing step: (i) the consumed or non-functioning solar module(s) are mechanically detach from the flexible substrate member sub-assembly, and (ii) the consumed or non-functioning solar module(s) are electrically detached adjacent solar modules.

According to a further aspect of the present invention, a solar panel assembly includes: a first solar module; a second solar module; and a pliable substrate member. The first solar modular comprises a first solar cell which is monocrystalline or polycrystalline. The first solar module is not sufficiently flexible to be foldable;

the second solar modular comprises a first solar cell which is monocrystalline or polycrystalline. The second solar module is not sufficiently flexible to be foldable. The substrate member is generally flat and includes a first major surface. The first solar cell is mechanically connected to the first major surface of the substrate member. The second solar cell is mechanically connected to the first major surface of the substrate member. The first solar module is electrically connected to the second solar module. The first solar module is sufficiently spaced away from the second solar module so that the substrate member can be folded into a folded configuration where the first and second solar modules are substantially aligned in the form of a stack arrangement.

### BRIEF DESCRIPTION OF THE DRAWINGS

The present invention will be more fully understood and appreciated by reading the following Detailed Description in conjunction with the accompanying drawings, in which:

FIG. 1 is an exploded, perspective view of a first embodiment of a solar module according to the present invention;

FIG. 2 is an orthographic top view of a first embodiment of a solar panel according to the present invention;

FIG. 3 is an orthographic side view of a portion of the first embodiment solar panel;

FIG. 4 is a flow chart showing a first process embodiment according to the present invention;

FIG. 5 is a perspective, exploded view of a second embodiment of a solar cell assembly according to the present invention; and

FIG. 6 is an orthographic top view of a third embodiment of a solar cell assembly according to the present invention.

### DETAILED DESCRIPTION OF THE INVENTION

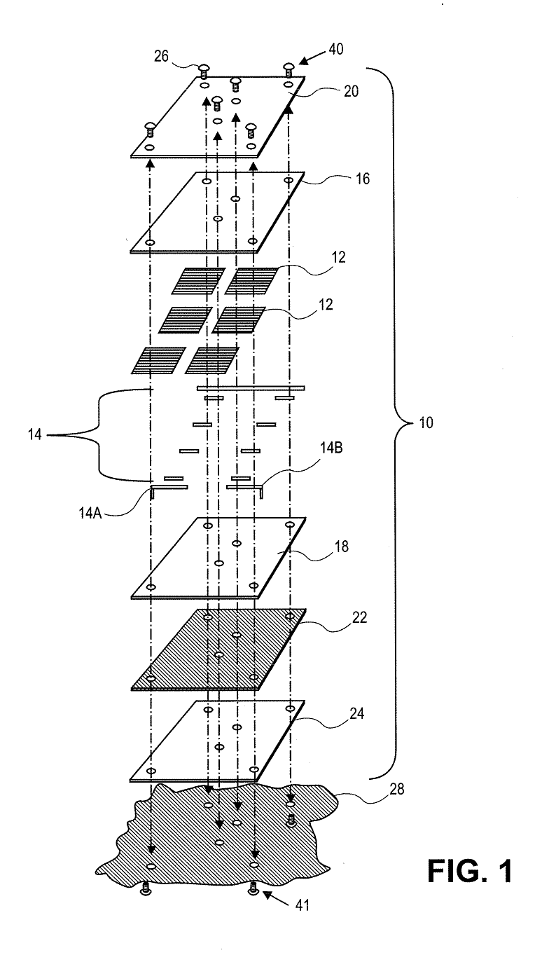

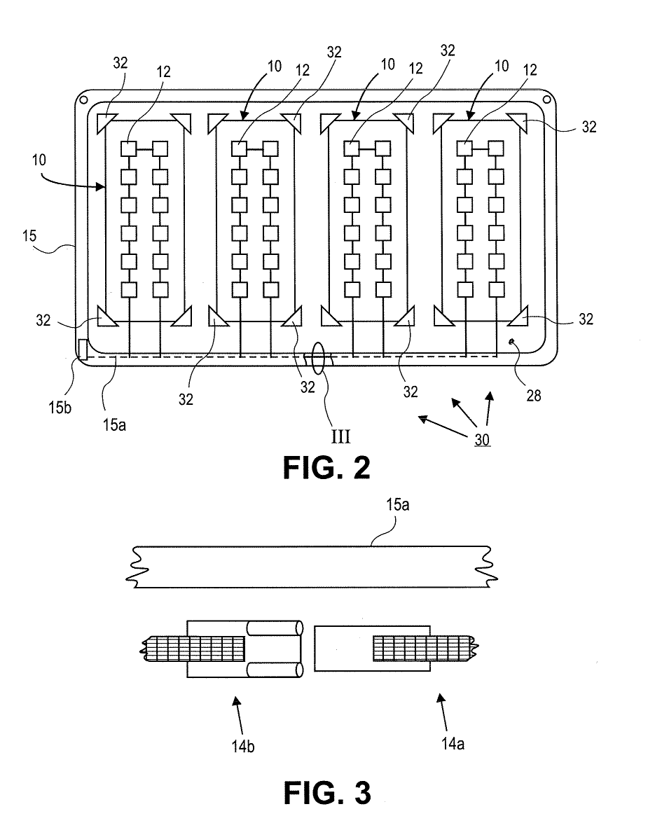

FIGS. 1 to 3 show solar cell assembly 30 including: solar modules 10; securement structures 32,40,41; and wire harness 15;; and flexible substrate sub-assembly 15,28. As shown in FIG. 1, each module 10 includes: solar cells 12; uppermost EVA sheets 16; wire set 14; ETFE sheet 20; flame resistant meta-aramid material sheet 22; removable rivets 26,40,41; intermediate EVA sheet 18; and lowermost EVA sheet 24. Wire set 14 includes flat input connector 14a and flat output connector 14b (see FIG. 3). As shown in FIG. 2, the flexible substrate sub-assembly includes: wire harness 15; and flexible substrate 28.

Referring to the drawings, in which like reference numerals refer to like parts throughout, there is seen in FIG. 1 a solar module, designated generally by reference numeral 10, comprising a plurality of solar cells 12 that are interconnected in series to one another by wire set 14. Wire set 14 is comprised preferably of flat wire segments so as to reduce the thickness of the assembly when folded. Wire set 14 and cells 12 are sandwiched between upper and lower sheets of ethylene vinyl acetate (EVA) 16, 18. To add structural integrity to the assembly, upper EVA panel 16 includes a sheet of ethylene tetrafluoroethylene (ETFE) 20 that encapsulates the assembly, while lower EVA sheet 18 includes layer of sheeting which includes a substrate fiber panel 22 followed by another EVA panel 24. Components 20, 16, 12, 14, 18, 22 and 24 are heat pressed (that is, laminated) together to form a solar module in the form of a laminated stack. In the laminated stack: (i) the EVA sheets act as adhesive, which hold the various laminated layers together as a single piece; (ii) the TFE sheet provides protection for the top surface of the solar module (which will generally be exposed to the elements, and may be deployed in severe weather and/or environmental conditions; (iii) the ETFE sheet may be treated to reduce reflection and glare when the solar module is in use in the sunlight; (iv) the ETFE sheet may vary in thickness depending upon the application (for example, 6 mil ETFE or 4 mil ETFE); (v) the ETFE sheet is preferred as a topmost layer because ETFE is tolerant of ultraviolet radiation (which is part of sunlight); and (vi) the solar cells are preferably monocrystalline or polycrystalline (to facilitate high efficiency in converting radiant energy into electrical energy). In many, if not most, preferred embodiments, the module 10 will not be flexible, pliable and/or foldable. For example, monocrystalline and poly crystalline solar cells are not foldable (at least under current conventional technologies). Also, the other layers of the stack, such as the ETFE sheet and/or the Nomex sheet 22 may not be very flexible and/or foldable. For military applications, both the modules and the larger assembly should preferably meet any applicable military specifications, such as milspec 810F. When making the laminated stack, care must be taken with the time temperature and pressure to prevent the formation of air bubbles within the laminate structure.

As will be discussed below, the solar modules of assembly 30 are primarily secured to the larger flexible substrate by corner-holding structures 32. However, in this embodiment, removable rivets 26, 40, 41 are also part of the securement hardware set, along with the corner-holding structures, that detachable mechanically connect each solar module to the larger flexible substrate. It is noted that the rivets must be removable in order for the mechanical connection (se DEFINITIONS section) between the module and the larger flexible substrate to be considered as “detachably attachable.” In other embodiments, the securement hardware set will include only corner-holding structures, but no removable rivets. In still other embodiments, the securement hardware set will include only removable rivets, but no corner holding structures. In other embodiments, this securement hardware set may include other detachably attachable connection hardware such as removable adhesive (for example, heat releasable EVA), hook and latch fastener or threaded hardware. Rivets 26, or other connectors, affix the ETFE 20 to the upper EVA panel 16 and the layers of rip stop backing 25, EVA panel 24 and substrate panel 22 to lower EVA panel 18. Whatever securement hardware is used, it should preferably be thin. For example, the use of hook and latch fastener fabric to secure the module to the larger flexible substrate is not currently preferred because the hook and latch fabric adds too much thickness when the solar cell assembly is in the folded configuration.

As shown in FIGS. 1 and 2, the solar module 10 is detachably attached to the flexible substrate sheet 28 by the removable rivets and the corner-holding structures. The larger flexible substrate 28 is preferably: (i) pliable; (ii) foldable; (iii) lightweight; and/or (iv) relatively thin. In this embodiment, the larger flexible substrate is made of a strong and light type of nylon referred to as “rip stop material.” In other preferred embodiments, other material may be used such as canvas or canvas-like material (which may be coated with silicone on one or both sides). One example of a preferred canvas-like material is 300 denier Cordura. The larger fabric substrate may have grommeted holes at its perimeter or corners in order to mechanically connect the solar cell assembly to larger structures (such as a frame, a tent or a blimp). More specifically, the grommets can protect the substrate from tearing even as it is held in place during high winds or the like.

As shown in FIG. 2, wiring harness 15 is the wiring (if any) that is built into the larger flexible substrate. In preferred embodiments, much of the wring will consist of direct electrical connections between adjacent solar panels (see FIGS. 2 and 3), which wiring is considered to be part of the solar modules and not part of the wiring harness of the substrate sub-assembly 15, 28. However, embodiment 30 does include a wire harness in order to: (i) electrically connect a first end of the series-connected modules to juncture box 15b; (ii) electrically connect a second end of the series-connected modules to juncture box 15b; (iii) to provide for a juncture box so that the solar cell assembly can be detachable electrically connected to other components (for example, other solar cell assemblies and/or a battery); and (iv) to provide blocking diodes, as desired by the designer, to prevent unwanted current flows. The wiring harness will sometimes consist of no more than terminal connections between the input/output terminals of electrically-adjacent solar modules. Harness 15 includes input and output terminal set 15a that runs along a portion of the outside perimeter of the solar cell assembly in this example. In other embodiments, the wiring harness may include additional current carrying paths to help electrically connect the various modules to each other (in series or otherwise).

As shown in FIGS. 1 and 3, it is wire set 14 that interconnects electrically-adjacent solar modules. More specifically, input connector 14a and output connector 14b are a flat style of detachable electrical connector and form the electrical connections used to connect the modules in series in this embodiment. FIG. 3 shows a detachably attachable electrical connection that connects two adjacent solar modules including flat pin accommodating socket 14b and flat pin 14a. In this preferred embodiment, the solar cells of the solar cell set are connected with each other in series so that there is a current path from each solar cell to the input/output terminals of the solar module, and so that the voltage of each solar module is added together to form the aggregate voltage of the solar cell assembly as a whole. However, as will be appreciated by those of skill in the art, there may be other ways of electrically connecting the solar cells so that there is a current path from each solar cell to the input/output terminals of the module. Also, additional circuitry components, such as diodes, may be present in the wire sets of some embodiments of the present invention.

As shown in FIG. 1, in solar module 10 there are six solar cells arranged in a 2 by 3 rectangular array. However, other embodiments may have other quantities of solar cells per module and/or may have different arrangements of solar cells. For example, the solar modules 10 of FIG. 2 are shown with twelve solar cells per module (for a total of 48 solar cells for the entire solar cell assembly 30). In one preferred embodiment, each solar module is 10.25 inches by 15.50 inches.

According to the preset invention, four modules 10 (twelve cell style) are detachably attached to a common backing of rip stock 28 (see FIG. 2) and interconnected in series by wire set 14 to build a solar cell module assembly, designated generally by reference numeral 30. Each module 10 may be secured to rip stock 28 by positioning within Velcro pockets 32 that are arranged such that the corners of modules 10 will fit securely therein. Alternatively, or additionally, other types of securement structures may be used to detachably mechanically connect the modules to the solar panel. For example, snaps or turnbuckles may be used. Also, as will be discussed below, heat releasable agent may be used to form the mechanically detachable mechanical connection between module and host substrate sheet.

According to one aspect of the present invention, assembly 30 may be folded for ease in transport despite the fact that its constituent solar modules are not flexible and not foldable. To facilitate the folding of assembly 30 each individual module 10 is preferably arranged along parallel axes with the other modules 10 and with a slight spacing in between each adjacent module. The assembly 30 may then be folded at the spacings between successive modules 10.

As shown in FIG. 2, in assembly 30, the assembly is arranged to have a capacity of four solar modules, but other embodiments will be designed to have other quantities of solar modules per solar cell assembly. In this example, the assembly can be folded (for example, fan folded) into four sections, one for each solar module. When in the folded configuration, the assembly becomes much easier to handle with a small and compact footprint. In this example, the solar cells, the solar modules and the solar cell assembly each have a rectangular shape, but other embodiments may use different shapes for these components.

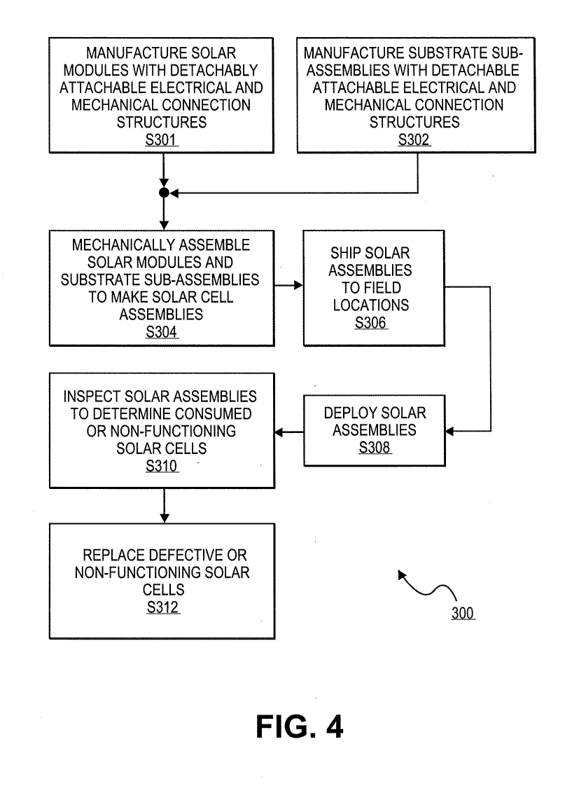

FIG. 4 shows process 300 according to the present invention. At steps S301 and S302 solar modules and flexible solar cell substrate assemblies are manufactured roughly in parallel. At least in a mass production environment, it may be advantageous to separately inventory and fulfill the solar modules on a schedule independent of the schedule for flexible substrate members. The present invention facilitates that manufacturing independence by making the solar cell modules detachable from the rest of the solar cell assembly and preferably also interchangeable with each other. For example, in assembly 30 (see FIG. 2), all four solar cells are interchangeable with each other. For example, they have the same size and shape and electrical properties. The fact that the solar modules are constructed separately from the larger flexible substrate sub-assembly in the present invention leads to some subtle, but potentially important, advantages of the present invention. Besides the logistics advantages, it should be kept in mind that the relatively-small solar modules of the present application are generally easier to laminate and/or test than a full assembly would be. For example, a smaller laminating machine can be used to make a 10 inch by 16 inch module, than to laminate a complete assembly measuring several feet by several feet. Also, infrared camera testing and/or electroluminescence testing will generally be easier for a small module than for a complete solar cell assembly. Furthermore, if a module is determined to be defective, ten only the defective module must be scrapped, rather than scrapping the complete solar cell assembly.

Processing proceeds to step S304, where the solar modules are assembled with the substrate assemblies. As discussed above, this assembly involves: (i) a mechanically detachable attachable connection between each module and is flexible substrate member, and (ii) an electrically detachable connection with adjacent module(s). For example, in the embodiment of FIGS. 1 to 3: (i) the four (4) modules 10 are each inserted into the corner structures 32 of the flexible member sub-assembly 28,32, and (ii) the four modules are connected in series using connectors as shown in FIG. 3.

Processing proceeds to step S306, where the solar assemblies are shipped to their field locations (for example, the site of a natural disaster). The solar assemblies may be folded as part of the shipping process. If they are folded, it is preferable to fold them so that the fold lines do not intersect the solar modules 10, which are generally relatively inflexible as compared to the flexible substrate 28.

Processing proceeds to step S308. The solar assemblies are deployed at the deployment site. That means they are set up and then used to generate electricity from the sunlight. Generally, they are electrically connected, directly or indirectly, to a battery, or other electrical charge storage device.

Processing proceeds to step S310, where the solar assemblies are inspected for consumed or non-functioning modules. At step S312, the consumed or non-functioning modules are replaced by exploiting the detachably attachable mechanical and electrical connections described herein. In some embodiments, the module which has been removed is repaired and replaced (into its old solar cell assembly, or a different solar cell assembly that needs a solar module). For example, in a military application, some solar cells may be damaged by enemy bullets so that one or more modules need to b replaced, but, according to the present invention, the entire solar cell assembly will not need to b replaced. This is especially helpful because solar modules generally cost a couple of hundred dollars apiece, but solar cell assemblies usually cost several thousand dollars.

A currently-preferred variation of the embodiment of FIGS. 1 to 3 will now be discussed. In this variation, backing panel 25, rivets (see rivet connect points 40,41) and corner-securing structures 32 are omitted. In this variation, instead of using the corner structures as the securement hardware set to detachably attach the modules to the larger substrate as in embodiment 30, EVA panel 24 of each module serves as the securement hardware set that detachably mechanically attaches the module to the larger flexible substrate. Specifically, EVA panel 24 is a heat releasable chemical bonding agent. In this currently-preferred variation, panel 24 is heated, in place on the larger substrate, in order to bond the module to the larger substrate to form the detachable mechanical connection. Preferably EVA panel 24 is about 1 millimeter thick (EVA is quite flexible at this low thickness).

If it is ever desired to replace the module, EVA layer 24 is reheated back up to its release temperature to release its bond with the larger substrate, and the module is then removed. It is noted that the heating of EVA layer 24 (that is, the lowermost EVA layer) will also “release” the other EVA layers in the stack of the module, but this should not be a problem if the module is handled carefully whenever it is heated to form or release a mechanical connection with the larger substrate.

For embodiments that use EVA as the securement hardware, it is noted that the heat release temperature is 121 degrees Celsius, and this temperature should be maintained for 20 minutes. Other heat releasable bonding agents may have different release times/temperatures, but solar module designers should be sure the that heat required to release the bonding agent: (i) will not be experienced as part of standard operating conditions when the module is harvesting sunlight; and (ii) that the heat level required does not harm or degrade the performance of the other components of the solar module and/or the larger substrate sheet. After the solar module has been removed from the larger substrate, it will generally be necessary to replace or restore this lowermost EVA layer before the module can be re-connected to another substrate sheet.

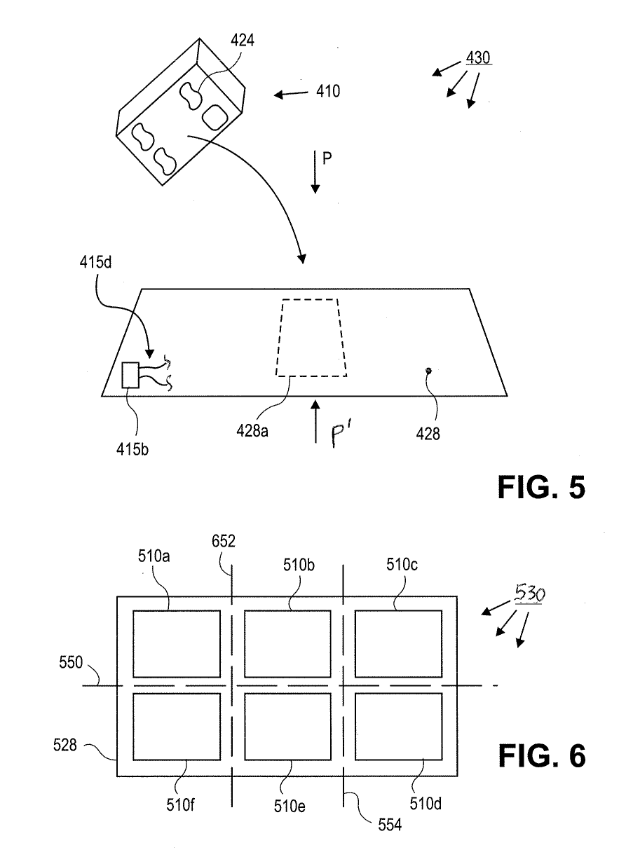

Referring now to FIG. 5, solar cell assembly 430 includes: solar cell 410; wiring harness input/output terminals 415a; wiring harness juncture box 415b; flexible substrate 428 (including module placement area 428a); and compression direction arrows P and P′. In this embodiment, the lowermost layer of module 410 is heat-releasable EVA adhesive layer 424. As shown in FIG. 5, EVA adhesive layer 424 does not extend over the entire footprint of the laminate stack. This is to help make sure that the module can be reliably detached from the solar cell assembly with the proper application of heat, time and force. If there is too much adhesive, then it may be difficult to heat the module in such a way so that it can be removed without damage or dislocation to the other layers of the laminate stack.

Referring now to FIG. 6, assembly 530 includes non-foldable solar modules 510a,b,c,d,e,f; large flexible substrate 528; and fold lines 550,552,554. In this embodiment, the solar cells are permanently attached to the large flexible substrate. However, the modules are still spaced apart, and otherwise located, so that the assembly can be folded into a six section stack along the fold lines located between the non-foldable modules.

### DEFINITIONS

Any and all published documents mentioned herein shall be considered to be incorporated by reference, in their respective entireties. The following definitions are provided for claim construction purposes:

Present invention: means “at least some embodiments of the present invention,” and the use of the term “present invention” in connection with some feature described herein shall not mean that all claimed embodiments (see DEFINITIONS section) include the referenced feature(s).

Embodiment: a machine, manufacture, system, method, process and/or composition that may (not must) be within the scope of a present or future patent claim of this patent document; often, an “embodiment” will be within the scope of at least some of the originally filed claims and will also end up being within the scope of at least some of the claims as issued (after the claims have been developed through the process of patent prosecution), but this is not necessarily always the case; for example, an “embodiment” might be covered by neither the originally filed claims, nor the claims as issued, despite the description of the “embodiment” as an “embodiment.”

First, second, third, etc. (“ordinals”): Unless otherwise noted, ordinals only serve to distinguish or identify (e.g., various members of a group); the mere use of ordinals shall not be taken to necessarily imply order (for example, time order, space order).

Electrically Connected: means either directly electrically connected, or indirectly electrically connected, such that intervening elements are present; in an indirect electrical connection, the intervening elements may include inductors and/or transformers.

Mechanically connected: Includes both direct mechanical connections, and indirect mechanical connections made through intermediate components; includes rigid mechanical connections as well as mechanical connection that allows for relative motion between the mechanically connected components; includes, but is not limited, to welded connections, solder connections, connections by fasteners (for example, nails, bolts, screws, nuts, hook-and-loop fasteners, knots, rivets, quick-release connections, latches and/or magnetic connections), force fit connections, friction fit connections, connections secured by engagement caused by gravitational forces, pivoting or rotatable connections, and/or slidable mechanical connections.

Receive/provide/send/input/output: unless otherwise explicitly specified, these words should not be taken to imply: (i) any particular degree of directness with respect to the relationship between their objects and subjects; and/or (ii) absence of intermediate components, actions and/or things interposed between their objects and subjects.

Module/Sub-Module: any set of hardware, firmware and/or software that operatively works to do some kind of function, without regard to whether the module is: (i) in a single local proximity; (ii) distributed over a wide area; (ii) in a single proximity within a larger piece of software code; (iii) located within a single piece of software code; (iv) located in a single storage device, memory or medium; (v) mechanically connected; (vi) electrically connected; and/or (vii) connected in data communication.

Solar module: an integrally formed assembly of one or more solar cells that is at least substantially formed as a single-piece main body in the form of a laminate d package (which may have terminals extending from it).

Unless otherwise explicitly provided in the claim language, steps in method or process claims need only be performed that they happen to be set forth in the claim only to the extent that impossibility or extreme feasibility problems dictate that the recited step order be used. This broad interpretation with respect to step order is to be used regardless of alternative time ordering (that is, time ordering of the claimed steps that is different than the order of recitation in the claim) is particularly mentioned or discussed in this document. Any step order discussed in the above specification, and/or based upon order of step recitation in a claim, shall be considered as required by a method claim only if: (i) the step order is explicitly set forth in the words of the method claim itself; and/or (ii) it would be substantially impossible to perform the method in a different order. Unless otherwise specified in the method claims themselves, steps may be performed simultaneously or in any sort of temporally overlapping manner. Also, when any sort of time ordering is explicitly set forth in a method claim, the time ordering claim language shall not be taken as an implicit limitation on whether claimed steps are immediately consecutive in time, or as an implicit limitation against intervening steps.

What is claimed is:

1. A solar panel assembly comprising:
a first securement hardware set;
a first solar module; and
a flexible substrate sub-assembly;
wherein:
the flexible substrate sub-assembly comprises a first flexible member;
the first securement hardware set is structured, located, sized, shaped and/or connected so that the first securement hardware set mechanically connects the first solar module to the flexible substrate member in a detachably attachable manner;
the first solar module comprises a first set of solar cell(s) and a first wire set;
the first wire set comprises an input terminal and an output terminal; and
the first wire set is structured, located, sized, shaped and/or connected to provide a current path from each solar cell of the first set of solar cells to the input and output terminals of the first wire set.

2. The assembly of claim 1 wherein the first wire set is further structured, located, sized, shaped and/or connected to provide a current path from each solar cell of the first set of solar cells to the input terminal and output terminals of the first wire set by providing a series electrical connection passing through each of the solar cell(s) of the first set of solar cell(s).

3. The assembly of claim 1 wherein the flexible substrate member is made of pliable fabric.

4. The assembly of claim 1 wherein:
the solar cell(s) of the first set of solar cell(s) each comprise a plurality of corners;
the first securement hardware set comprises a plurality of corner-holding structures; and
each corner holding structure of the plurality of corner holding structures is structured, sized, shaped, located and/or connected to releasably secure a corner of a solar cell.

5. The assembly of claim 1 wherein the first securement hardware set comprises heat releasable adhesive material.

6. The assembly of claim 1 wherein the flexible substrate member is made of rip stock.

7. The assembly of claim 1 wherein:
the first solar module further comprises a first plastic layer, a second plastic layer and a third plastic layer;
the first set of solar cell(s) and the second plastic layer are located between the first plastic layer and the third plastic layer;
the first set of solar cell(s) is located between the second plastic layer and the third plastic layer; and
the first wire set is located between the first plastic layer and the third plastic layer, except for the input and output terminals input and output terminals of the first wire set which extend outside of the space between the first and third plastic layers.

8. The assembly of claim 1 wherein:
the first plastic layer is made of ETFE;
the second and third plastic layers are made of EVA.

9. The assembly of claim 7 wherein:
the first solar module further comprises a first fiber panel;
the first fiber panel is located between the first plastic layer and the third plastic layer; and
the first fiber panel comprises at least one of the following materials: carbon, Nomex and/or garolite.

10. The assembly of claim 7 wherein:
the first solar module further comprises a rip stop backing material layer;
the second plastic layer, the third plastic layer and the first set of solar cell(s) are all located between the first plastic layer and the rip stop backing material layer.

11. The assembly of claim 1 wherein the first wire set substantially consists of flat wire segments.

12. The assembly of claim 1 wherein the first set of solar cells of the first solar module are of one of the following types: monocrystalline, or polycrystalline.

13. The assembly of claim 12 wherein the first set of solar cells of the first solar module are monocrystalline.

14. The assembly of claim 2 wherein the input and output terminals each respectively comprise an electrical connector that is structured, sized, shaped and/or connected to form detachably attachable electrical connections with respective mating connectors.

15. The assembly of claim 1 wherein the first securement hardware comprises a heat releasable chemical bonding agent.

16. A method of using a solar panel to convert solar radiation into electricity, the method comprising the steps of:
assembling a solar cell assembly comprising a plurality of solar modules and a flexible substrate member sub-assembly;
deploy plurality of solar cell assemblies;
inspect solar assemblies to determine consumed or non-functioning solar module(s); and
subsequent to the deploying step, replacing consumed or non-functioning solar module(s); and
subsequent to the replacing step, continuing to operate the solar cell assembly to generate electricity;
wherein:
at the assembling step: (i) the plurality of solar modules are mechanically detachably attached to the flexible substrate member sub-assembly, and (ii) the solar modules are electrically detachably connected to each other; and
at the replacing step: (i) the consumed or non-functioning solar module(s) are mechanically detach from the flexible substrate member sub-assembly, and (ii) the consumed or non-functioning solar module(s) are electrically detached adjacent solar modules.

17. The method of claim 16 further including the following step:
subsequent to the assembling step and prior to the deploying step, shipping the assembled solar cell assembly to a deployment site.

18. The method of claim 17 wherein the shipping step includes the following sub-step:
folding the solar cell assembly so that the fold lines in the flexible substrate sub-assembly do not intersect the solar modules of the first plurality of solar modules.

19. A solar panel assembly comprising:
a first solar module;
a second solar module; and
a pliable substrate member;
wherein:
the first solar modular comprises a first solar cell which is monocrystalline or polycrystalline;
the first solar module is not sufficiently flexible to be foldable;
the second solar modular comprises a first solar cell which is monocrystalline or polycrystalline;
the second solar module is not sufficiently flexible to be foldable;
the substrate member is generally flat and includes a first major surface;
the first solar cell is mechanically connected to the first major surface of the substrate member;
the second solar cell is mechanically connected to the first major surface of the substrate member;
the first solar module is electrically connected to the second solar module; and
the first solar module is sufficiently spaced away from the second solar module so that the substrate member can be folded into a folded configuration where the first and second solar modules are substantially aligned in the form of a stack arrangement.

20. The assembly of claim 19 wherein:
the first solar cell of the first solar module is monocrystalline; and
the first solar cell of the second solar module is monocrystalline.
